(19) United States
(12) Patent Application Publication
(10) Pub. No.: US 2023/0068211 A1
(43) Pub. Date: Mar. 2, 2023

(54) DEVICE FOR TRANSFERRING ELECTRONIC COMPONENT AND METHOD FOR TRANSFERRING ELECTRONIC COMPONENT

(71) Applicant: SKIILEUX ELECTRICITY INC., Taoyuan City (TW)

(72) Inventors: SHENG-HSIANG YU, Taoyuan City (TW); SHANG-WEI TSAI, Taoyuan City (TW); TE-FU CHANG, Taoyuan City (TW); CHENG-CHIEH CHANG, Taoyuan City (TW)

(21) Appl. No.: 17/830,349

(22) Filed: Jun. 2, 2022

(30) Foreign Application Priority Data
Aug. 19, 2021 (TW) 110130605

(51) Int. Cl. B32B 43/00; B23K 26/067; B23K 26/53

(52) U.S. Cl. CPC B32B 43/006; B23K 26/067; B23K 26/53; H01L 21/6835

(57) ABSTRACT

A device for transferring electronic component, comprising: an energy source used to project an energy beam; a first frame used to carry a carrier loaded with electronic component; a second frame used to carry a substrate for receiving the aforesaid electronic component; a beam splitting element arranged between the first frame and the energy source; and a focusing device arranged between the first frame and the beam splitting element. The present invention also relates to a method of transferring electronic component. The device for transferring electronic component and the method for transferring electronic component of the present invention can be applied in the manufacturing process of display.

### CROSS-REFERENCE TO RELATED APPLICATION

This non-provisional application claims priority under 35 U.S.C. § 119(a) on Patent Application No(s).110130605 filed in Taiwan, R.O.C. on Aug. 19, 2021, the entire contents of which are hereby incorporated by reference.

### BACKGROUND OF THE INVENTION

### 1. Field of the Invention

The present disclosure relates to devices for transferring an electronic component, and in particular to a device adapted to transfer an electronic component and comprising a beam-splitting element. The present disclosure further relates to methods for transferring an electronic component and, more particularly, to a method adapted to transfer an electronic component and comprising the step of splitting an energy beam into at least two sub-beams.

### 2. Description of the Related Art

In recent years, various electronic devices come with increasingly robust functions, thereby requiring an increasingly large number of electronic components. Furthermore, with the ongoing trend toward miniaturization of their electronic components, the electronic devices not only attain reduction of their volume which might otherwise be unnecessarily large but also meet consumer needs.

Therefore, it is important to come up with a solution to transferring electronic components precisely during an electronic device manufacturing process.

For instance, in recent years, there is a trend toward LED (light emitting diode) display units each composed of micron-scale LED chips arranged in an array so as to meet the demand for high resolution.

Transferring LED chips entails carrying out an important technique essential to a manufacturing process of LED display units. For example, a radiation ray, such as laser, is projecting onto LED chips to be transferred in order to overcome the adhesion between each LED chip and a carrier and thus enable the LED chips to separate from the carrier.

However, there is room for improvement in the accuracy and efficiency of conventional devices for transferring an electronic component and conventional methods for transferring an electronic component. Therefore, one of the important trends of development in this field is to transfer electronic components quickly and accurately.

### BRIEF SUMMARY OF THE INVENTION

To overcome a drawback of the conventional devices for transferring an electronic component and the conventional methods for transferring an electronic component, that is, unsatisfactory accuracy and efficiency, the present disclosure provides a novel device for transferring an electronic component and a novel method for transferring an electronic component.

In order to achieve the above and other objectives, the present disclosure provides a device for transferring an electronic component, comprising:

an energy source for projecting an energy beam;

a first frame for carrying a carrier loaded with the electronic component;

a second frame for carrying a substrate for use in receiving the electronic component, wherein the substrate faces an electronic component-loaded side of the carrier;

a beam-splitting element disposed between the first frame and the energy source and lying on a projection path of the energy beam to split and project the energy beam onto an electronic component-free side of the carrier, wherein an irradiation area is defined on the beam-splitting element and adapted to be irradiated by the energy beam, with the irradiation area having therein at least two discrete penetrable portions and a nonpenetrable portion; and a focusing apparatus disposed between the first frame and the beam-splitting element and lying on the projection path of the energy beam to focus the energy beam thus split.

Regarding the device, the energy source is a laser source.

Regarding the device, the irradiation area has therein two penetrable portions.

Regarding the device, the irradiation area has therein three penetrable portions.

The device further comprises a beam-expanding component disposed between the energy source and the beam-splitting element and adapted to expand a radial length of the energy beam projected from the energy source.

Regarding the device, the distance between the first frame and the focusing apparatus is adjustable.

In order to achieve the above and other objectives, the present disclosure provides a method for transferring an electronic component, comprising the steps of:

providing a carrier, wherein a surface of the carrier is loaded with an electronic component;

providing a substrate;

allowing a side of the substrate to face an electronic component-loaded side of the carrier, and maintaining an appropriate distance between the carrier and the substrate;

providing an energy source for projecting an energy beam;

splitting the energy beam into at least two sub-beams;

focusing the at least two sub-beams, such that projection paths of the sub-beams are not parallel to each other;

adjusting the distance between the carrier and the energy source as needed; and

irradiating appropriate points on the electronic component-free side of the carrier with the at least two sub-beams to allow the electronic component to be separated from the carrier and transferred to the substrate.

Regarding the method, the energy source is a laser source.

Regarding the method, the energy beam is split into two sub-beams.

Regarding the method, the electronic component is an LED component with a P terminal and an N terminal, both lying on the same side.

Regarding the method, the two sub-beams fall on points on a side of the carrier, respectively, and the P terminal and N terminal of the LED component are absent from the side of the carrier.

Regarding the method, the energy beam is split into three sub-beams.

Regarding the method, a beam-splitting element is placed on a projection path of the energy beam and adapted to split the energy beam, wherein the beam-splitting element has a nonpenetrable portion and at least two discrete penetrable portions falling within the scope of the irradiation by the energy beam.

Regarding the method, the electronic component is affixed to the carrier with an adhesive, and the adhesive melts after being irradiated with the sub-beams, allowing the electronic component to separate from the carrier.

The device for transferring an electronic component and the method for transferring an electronic component according to the present disclosure are effective in quickly and accurately adjusting the spacing between at least two sub-speckles formed on the carrier by the at least two sub-beams, so as to transfer electronic components accurately and thereby enhance the efficiency of manufacturing electronic devices.

### BRIEF DESCRIPTION OF THE DRAWINGS

FIG. 1 is a cross-sectional view of a device for transferring an electronic component according to embodiment 1 of the present disclosure.

FIG. 2 is a top view of a beam-splitting element of the device for transferring an electronic component according to embodiment 1 of the present disclosure.

FIG. 3 is a schematic view of the flowchart of a method for transferring an electronic component according to embodiment 2 of the present disclosure.

### DETAILED DESCRIPTION OF THE INVENTION

A device for transferring an electronic component and a method for transferring an electronic component are provided according to the present disclosure and hereunder illustrated by specific embodiments. Persons skilled in the art can gain insight into its advantages and effects accordingly. The present disclosure can be implemented or applied in accordance with any other variant embodiments. Various modifications and changes may be made to the details described in the specification from different perspectives and for different applications without departing from the spirit of the present disclosure.

### Embodiment 1

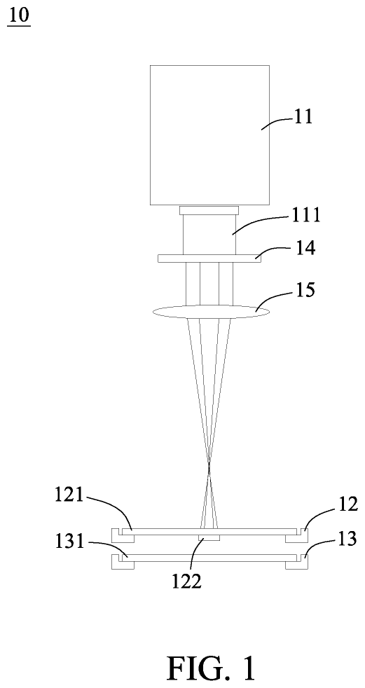

Referring to FIG. 1, in embodiment 1 of the present disclosure, a device 10 for transferring an electronic component, comprising: an energy source 11 for projecting an energy beam 111; a first frame 12 for carrying a carrier 121 loaded with an electronic component 122; a second frame 13 for carrying a substrate 131 for use in receiving the electronic component 122, wherein the substrate 131 faces the electronic component-loaded side of the carrier 121; a beam-splitting element 14 disposed between the first frame 12 and the energy source 11 and lying on a projection path of the energy beam 111 to split and project the energy beam 111 onto the electronic component-free side of the carrier 121; and a focusing apparatus 15 disposed between the first frame 12 and the beam-splitting element 14 and lying on the projection path of the energy beam 111 to focus the energy beam 111 thus split.

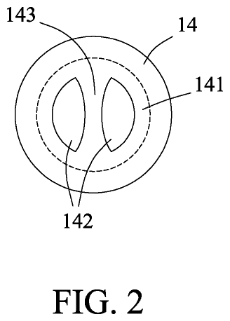

Referring to FIG. 2, an irradiation area 141 is defined on the beam-splitting element 14 and adapted to be irradiated by the energy beam 111. The irradiation area 141 has therein at least two discrete penetrable portions 142 and a nonpenetrable portion 143.

Referring to FIG. 1, the beam-splitting element 14 splits the energy beam 111 into at least two sub-beams. Then, the focusing apparatus 15 focuses the at least two sub-beams, such that the projection paths of the at least two sub-beams are not parallel to each other. At the moment, the distance between the carrier 121 and the energy source 11 is adjusted as needed, such that the at least two sub-beams fall on appropriate points on the electronic component-free side of the carrier 121, so as for the electronic component 122 to be separated from the carrier 121 and transferred to the substrate 131.

In this embodiment, the device 10 for transferring an electronic component enables the two sub-beams to fall on two different points on the electronic component-free side of the carrier 121, respectively, so as to enhance the precision of transferring the electronic component 122. Therefore, the device 10 for transferring an electronic component overcomes a drawback of the prior art, that is, when an electronic component is irradiated with only one speckle, the irradiation location deviates from the center of the electronic component, causing the electronic component to rotate or rupture in the course of transferal.

In this embodiment, the energy source 11 is a laser source, but the present disclosure is not limited thereto. Persons skilled in the art may choose to use any other energy sources as needed, provided that the energy sources provide sufficient energy to enable the electronic component 122 to separate from the carrier 121.

In this embodiment, the irradiation area 141 has therein two discrete penetrable portions 142, but the present disclosure is not limited thereto. In another embodiment, the irradiation area 141 has therein three, four, five or more discrete penetrable portions in order for the energy beam to be split into three, four, five or more sub-beams.

In another preferred embodiment of the present disclosure, the device 10 for transferring an electronic component further comprises a beam-expanding component disposed between the energy source and the beam-splitting element and adapted to expand the radial length of the energy beam projected from the energy source. The preferred embodiment is not restrictive of the position of the beam-expanding component. In yet another preferred embodiment, the beam-expanding component is disposed between the energy source and the focusing apparatus, whereas the beam-splitting element is disposed in the beam-expanding component. In still yet another preferred embodiment, the beam-expanding component is disposed between the beam-splitting element and the focusing apparatus.

In this embodiment, the nonpenetrable portion 143 is of a width of 1.6 mm, but the present disclosure is not limited thereto. With the width being fixed, the distance between dual speckles formed on the carrier 121 by the two sub-beams is determined by the distance (i.e., out-of-focus distance) between the carrier 121 and the focus of the two sub-beams, so as to meet practical needs. The relationship between the out-of-focus distance and the distance between the dual speckles is evaluated with a test and shown in Table 1 below.

TABLE 1

| Out-of-focus distance (μm) | Distance (μm) between dual speckles |
|---|---|
| 250 | 20 |
| 500 | 26 |
| 750 | 32 |
| 1000 | 39 |
| 1250 | 45 |

For instance, the electronic component 122 is an LED component whose P terminal and N terminal are on the same side and are separated by a distance of 35 μm. Thus, the distance (i.e., out-of-focus distance) between the carrier 121 and the focus of the two sub-beams is set to fall within the range of 750 μm-1000 μm. The two sub-beams fall on points of the carrier 121 (the points of the carrier 121 correspond in position to the P terminal and N terminal of the LED component), respectively, to enhance the precision of transferal of the LED component. Therefore, the device 10 for transferring an electronic component overcomes a drawback of the prior art, that is, when an LED component is irradiated with only one speckle, the irradiation location deviates from the center of the LED component, causing the LED component to rotate or rupture in the course of transferal.

In another preferred embodiment, the distance between the focusing apparatus and the first frame in the device for transferring an electronic component according to the present disclosure is adjustable. Specifically speaking, the first frame is driven with a driving apparatus, such that the distance between the first frame and the focusing apparatus is adjusted, so as to adjust the distance between the dual speckles formed on the carrier by the two sub-beams and thereby meet practical needs.

In another preferred embodiment, the beam-splitting element is a beam-splitting disk. A plurality of irradiation areas are defined on the beam-splitting disk and adapted to be irradiated by the energy beam. The irradiation areas are equidistant from the center of the beam-splitting disk. The nonpenetrable portions in the irradiation areas are of different widths. In this preferred embodiment, the device for transferring an electronic component is advantageous in that the beam-splitting disk is rotated to allow the energy beam to fall on different irradiation areas, such that the difference in the width of the nonpenetrable portions between the irradiation areas facilitates the adjustment of the distance between the dual speckles formed on the carrier by the two sub-beams, so as to meet practical needs.

### Embodiment 2

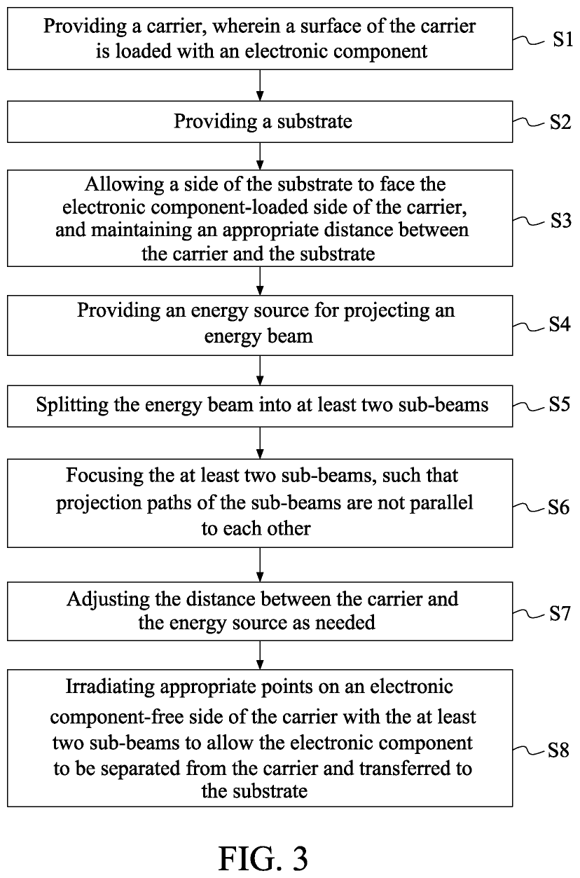

Referring to FIG. 3, in embodiment 2, a method for transferring an electronic component comprises the steps of: S1: providing a carrier, wherein a surface of the carrier is loaded with an electronic component; S2: providing a substrate; S3: allowing a side of the substrate to face the electronic component-loaded side of the carrier, and maintaining an appropriate distance between the carrier and the substrate; S4: providing an energy source for projecting an energy beam; S5: splitting the energy beam into at least two sub-beams; S6: focusing the at least two sub-beams, such that projection paths of the sub-beams are not parallel to each other; S7: adjusting the distance between the carrier and the energy source as needed; and S8: irradiating appropriate points on the electronic component-free side of the carrier with the at least two sub-beams to allow the electronic component to be separated from the carrier and transferred to the substrate.

The method of embodiment 2 is implemented with the device of embodiment 1 without placing any limitations on the present disclosure.

In this embodiment, the energy source is a laser source, but the present disclosure is not limited thereto. Persons skilled in the art may choose to use any other energy sources as needed, provided that the energy sources provide sufficient energy to enable the electronic component to separate from the carrier.

In this embodiment, the energy beam is split into two sub-beams, but the present disclosure is not limited thereto. Persons skilled in the art may allow the energy beam to split into three, four, five or more sub-beams as needed.

The method of embodiment 2 enables the two sub-beams to fall on different points on the electronic component-free side of the carrier, respectively, to enhance the precision of transferring the electronic component. Therefore, the method of embodiment 2 overcomes a drawback of the prior art, that is, when an electronic component is irradiated with only one speckle, the irradiation location deviates from the center of the electronic component, causing the electronic component to rotate or rupture in the course of transferal.

In a preferred embodiment, the electronic component is an LED component whose P terminal and N terminal lie on the same side to allow the two sub-beams to fall on two points on one side of the carrier (the side of the carrier faces away from the P terminal and N terminal of the LED component), respectively, to enhance the precision of transferring the LED component. Therefore, the method of this preferred embodiment overcomes a drawback of the prior art, that is, when an LED component is irradiated with only one speckle, the irradiation location deviates from the center of the LED component, causing the LED component to rotate or rupture in the course of transferal.

In a preferred embodiment, a beam-splitting element is placed on a projection path of the energy beam to split the energy beam. The beam-splitting element has a nonpenetrable portion and the at least two discrete penetrable portions falling within the scope of the irradiation by the energy beam, but the present disclosure is not limited thereto.

In a preferred embodiment, the electronic component is affixed to the carrier with an adhesive. After being irradiated with the sub-beams, the adhesive melts to enable separation of the electronic component from the carrier, but the present disclosure is not limited thereto.

In conclusion, a device for transferring an electronic component and a method for transferring an electronic component according to the present disclosure are effective in quickly and accurately adjusting the spacing between at least two sub-speckles formed on the carrier by the at least two sub-beams and accurately transferring an electronic component (for example, LED component), so as to enhance the efficiency of manufacturing electronic devices (for example, LED display units).

The embodiments are illustrative rather than restrictive of the present disclosure. Thus, modifications and changes may be made by persons skilled in the art to the embodiments without departing from the spirit and scope of the present disclosure. Accordingly, the legal protection for the present disclosure shall be defined by the appended claims.

What is claimed is:

1. A device for transferring an electronic component, comprising:
an energy source for projecting an energy beam;
a first frame for carrying a carrier loaded with the electronic component;
a second frame for carrying a substrate for use in receiving the electronic component, wherein the substrate faces an electronic component-loaded side of the carrier;
a beam-splitting element disposed between the first frame and the energy source and lying on a projection path of the energy beam to split and project the energy beam onto an electronic component-free side of the carrier, wherein an irradiation area is defined on the beam-splitting element and adapted to be irradiated by the energy beam, with the irradiation area having therein at least two discrete penetrable portions and a nonpenetrable portion; and
a focusing apparatus disposed between the first frame and the beam-splitting element and lying on the projection path of the energy beam to focus the energy beam thus split.

2. The device of claim 1, wherein the energy source is a laser source.

3. The device of claim 1, wherein the irradiation area has therein two penetrable portions.

4. The device of claim 1, wherein the irradiation area has therein three penetrable portions.

5. The device of claim 1, further comprising a beam-expanding component disposed between the energy source and the beam-splitting element and adapted to expand a radial length of the energy beam projected from the energy source.

6. The device of claim 1, wherein a distance between the first frame and the focusing apparatus is adjustable.

7. The device of claim 1, wherein the electronic component is an LED component whose P terminal and N terminal lie on the same side.

8. A method for transferring an electronic component, comprising the steps of:
providing a carrier, wherein a surface of the carrier is loaded with an electronic component;
providing a substrate;
allowing a side of the substrate to face an electronic component-loaded side of the carrier, and maintaining an appropriate distance between the carrier and the substrate;
providing an energy source for projecting an energy beam;
splitting the energy beam into at least two sub-beams;
focusing the at least two sub-beams, such that projection paths of the sub-beams are not parallel to each other;
adjusting a distance between the carrier and the energy source as needed; and
irradiating appropriate points on the electronic component-free side of the carrier with the at least two sub-beams to allow the electronic component to be separated from the carrier and transferred to the substrate.

9. The method of claim 8, wherein the energy source is a laser source.

10. The method of claim 8, wherein the energy beam is split into two sub-beams.

11. The method of claim 10, wherein the electronic component is an LED component with a P terminal and an N terminal, both lying on the same side.

12. The method of claim 11, wherein the two sub-beams fall on points on a side of the carrier, respectively, and the P terminal and N terminal of the LED component are absent from the side of the carrier.

13. The method of claim 8, wherein the energy beam is split into three sub-beams.

14. The method of claim 8, wherein a beam-splitting element is placed on a projection path of the energy beam and adapted to split the energy beam, wherein the beam-splitting element has a nonpenetrable portion and at least two discrete penetrable portions falling within the scope of the irradiation by the energy beam.

15. The method of claim 8, wherein the electronic component is affixed to the carrier with an adhesive, and the adhesive melts after being irradiated with the sub-beams, allowing the electronic component to separate from the carrier.
